(19) United States
(12) Patent Application Publication
(10) Pub. No.: US 2020/0295208 A1
(43) Pub. Date: Sep. 17, 2020

(54) APPARATUS AND METHOD FOR SOLAR PANEL

(71) Applicant: Erwang Mao, Palo Alto, CA (US)

(72) Inventor: Erwang Mao, Palo Alto, CA (US)

(21) Appl. No.: 16/355,739

(22) Filed: Mar. 16, 2019

(51) Int. Cl. H01L 31/048

(52) U.S. Cl. CPC H01L 31/048; H02S 40/34

(57) ABSTRACT

A photovoltaic module generates electrical power when installed on a roof. The module is constructed as a laminated sandwich having a transparent protective upper layer adhered to a photovoltaic layer with an encapsulation material. The photovoltaic layer is adhered to the top of a semi-rigid substrate layer with another encapsulation material. An outer portion of the said transparent protective upper layer is wraparound peripheral outer edges of the module, and further fixed to the bottom surface of the said semi-rigid substrate with adhesives. Preferably the outer portion of the transparent protective layer is affixed to the bottom surface of the substrate with seamless adhesive ring along outer peripheral edges of the surface, so that encapsulation materials are protected from water. The laminated module preferably has a layer of double stick tape on the bottom to adhere the module to the surface of a roof.

### BACKGROUND OF THE INVENTION

### 1. Field of the Invention

The present invention relates to solar panels/modules for generating electrical energy, and more particularly to photovoltaic panels/modules with no frames.

### 2. Description of the Related Art

Conventional photovoltaic modules for generating electrical power for residences and businesses are often flat and are placed on a portion of a roof that is exposed to the sun. Historically, such modules were placed on structures erected on the roof to support and protect the modules. More recently, photovoltaic modules have become available that can be mounted directly on a flat or tilted roof. See, for example, U.S. Pat. Nos. 7,531,740, and 7,557,291 to Flaherty, et al., the entire contents of which are incorporated herein by reference. These patents disclose such photovoltaic modules for roof-top installation.

A problem with above mentioned direct roof top attached crystalline silicon photovoltaic cell based solar modules is need for flexible frame around module peripheral, which could accumulate water or debris that could interfere with the module performance by blocking sun irradiation. U.S. Pat. No. 9,673,344 to Davey et al. addressed this issue by eliminating said flexible frame and adding a butylene sealant around module peripheral. However incorporating of said butylene sealant increase modules' material cost and build cost, as additional tool is needed for manufacturing of the modules on existing automated Si-wafer based module production line. Thus improved module design and construction method are needed for lowering module cost.

### SUMMARY OF THE INVENTION

The photovoltaic module described herein and illustrated in the attached drawings enables electricity-generating solar modules to be manufactured quickly.

In accordance with one aspect according to the present invention, a photovoltaic module has an upper transparent protective layer, and a photovoltaic layer positioned beneath the upper transparent protective layer. The photovoltaic layer has a plurality of electrically interconnected photovoltaic cells disposed in an array. A semi-rigid substrate layer is positioned beneath the photovoltaic layer. The upper transparent protective layer has a first surface facing the photovoltaic layer. A second surface of the upper protective layer, opposite to the first surface, is facing away from the photovoltaic layer. The semi-rigid substrate has a first surface facing the photovoltaic layer. A second surface of the rigid substrate layer, opposite to the first surface, is facing away from the photovoltaic layer. The said upper transparent protective layer has a first in-plane dimension wider than said first in-plane dimension of the semi-rigid substrate by at least 2 mm. The said upper transparent protective layer has a second in-plane dimension wider than the 2^{nd} in-plane dimension of the semi-rigid substrate by at least 2 mm. The said upper transparent layer is wrapped around all edges of said semi-rigid substrate layer. The wrapped upper protective layer is beneath the semi-rigid substrate layer. The first surface of the wrapped upper protective layer is facing the second surface of the semi-rigid substrate layer.

In accordance with another aspect of the present invention, a photovoltaic module has an upper transparent layer, and a photovoltaic layer positioned beneath the upper transparent layer. The photovoltaic layer includes a plurality of electrically interconnected photovoltaic cells disposed in a two-dimensional array and an electrical junction box on the same side of the module as the array of cells. A first layer of heat-activated transparent adhesive is interposed between the upper transparent layer and the photovoltaic layer to adhere the photovoltaic layer to the upper transparent layer. A semi-rigid layer is positioned beneath the photovoltaic layer. A second layer of heat-activated transparent adhesive is interposed between the photovoltaic layer and the semi-rigid layer to adhere the photovoltaic layer to the semi-rigid layer. The upper protective layer is disposed on top and about a periphery of the module, beneath said semi-rigid substrate layer, and beside said photovoltaic layer.

In accordance with a further aspect of the present invention, a method of making a photovoltaic module includes: (i) disposing a photovoltaic layer on an upper protective layer, the protective layer being wider and longer than the photovoltaic layer; (ii) disposing a semi-rigid substrate layer on the photovoltaic layer, the semi-rigid substrate layer being wider and longer than the photovoltaic layer, and narrower and shorter than the upper protective layer; (iii) the upper protective layer is folded around the photovoltaic layer and the semi-rigid and wrapped around peripheral of the semi-rigid substrate; and (iv) the folded part of upper protective layer is fixed on the semi-rigid substrate with suitable means forming a protective layer over the photovoltaic layer to prevent water and moisture ingress. Examples of suitable means can be, for example but not limited to, acrylic adhesives, butylene adhesives, etc.

### BRIEF DESCRIPTION OF THE DRAWINGS

Certain aspects in accordance with embodiments of the present invention are described below in connection with the accompanying drawing figures in which:

FIG. 1a illustrates a perspective view of a first embodiment of a laminated photovoltaic module according to the present invention with junction box showing conductors; FIG. 1b illustrates another perspective view of the same embodiment of the model;

FIGS. 2a and 2b illustrate a top view and rear view of the photovoltaic module of FIG. 1, respectively;

FIG. 3 illustrates a cross-section view of the photovoltaic module of FIGS. 1 a and 1b;

FIG. 4, illustrates a close up rear view of a preferred embodiment of the photovoltaic module of FIGS. 1a and 1b where front protective layer is fold and attach to the bottom surface of the substrate along module short edge.

FIG. 5 illustrates a close up rear view of a preferred embodiment of the photovoltaic module of FIGS. 1a and 1b; where front protective layer is further fold and attach to the bottom surface of the substrate along the module long edge secondly.

FIG. 6 illustrate a perspective view of a second embodiment of a laminated photovoltaic module according to the present invention with junction box showing conductors;

FIG. 7 illustrates the rear view of the photovoltaic module of FIG. 1 with preferred peel- and stick (PAS) tape pattern.

### DETAILED DESCRIPTION OF THE INVENTION

The present invention is directed at frameless photovoltaic modules with no edge sealants. Edge sealant is a general description and should be understand as polymeric materials that either block moisture or impeding moisture ingress into photovoltaic layer and encapsulation layers from all sides of the photovoltaic modules except top and bottom sides.

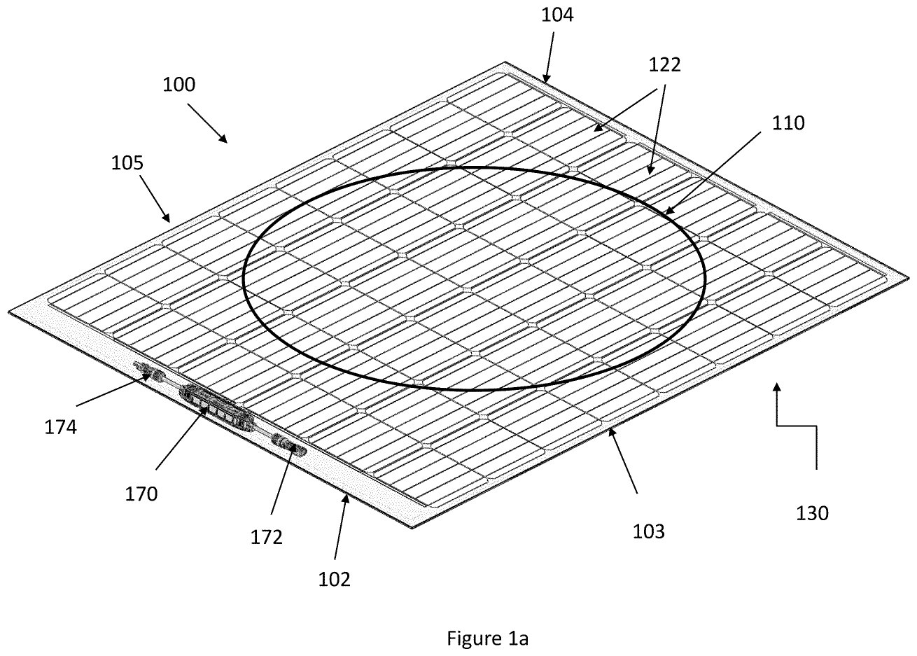

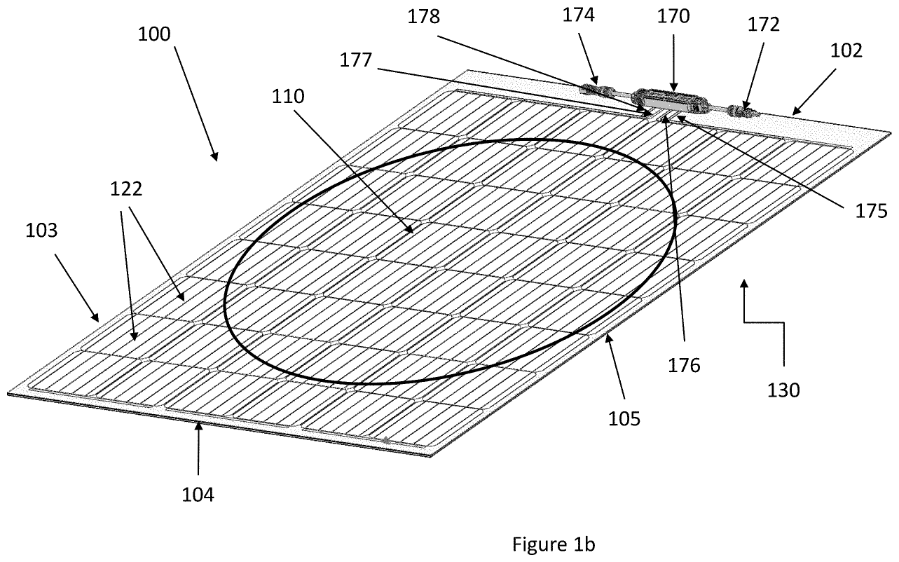

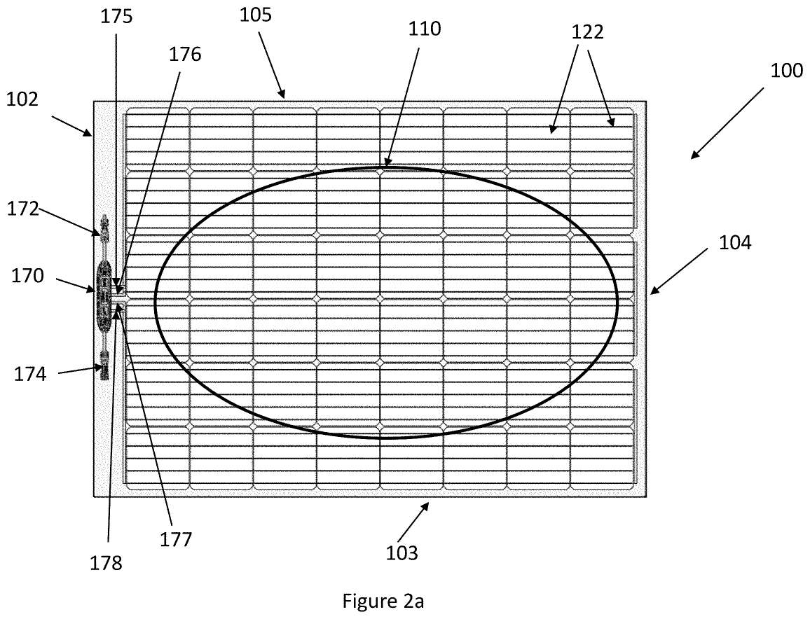

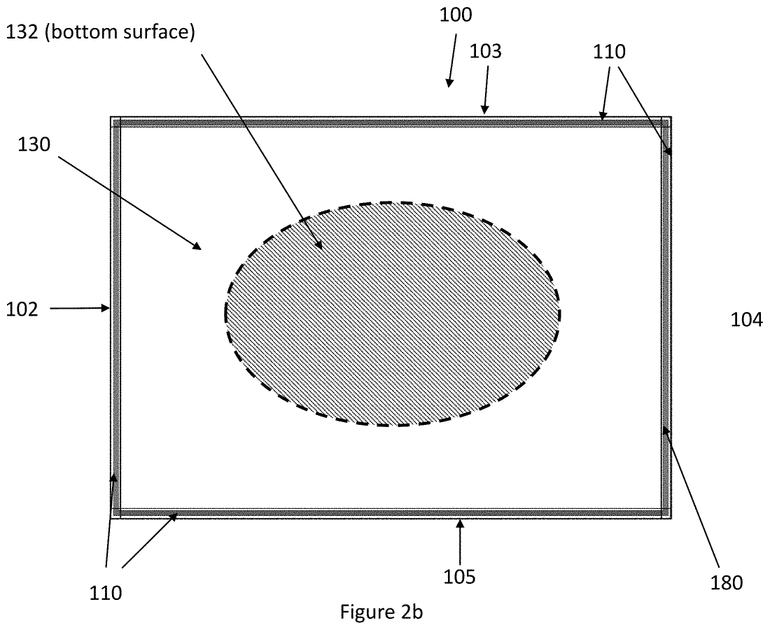

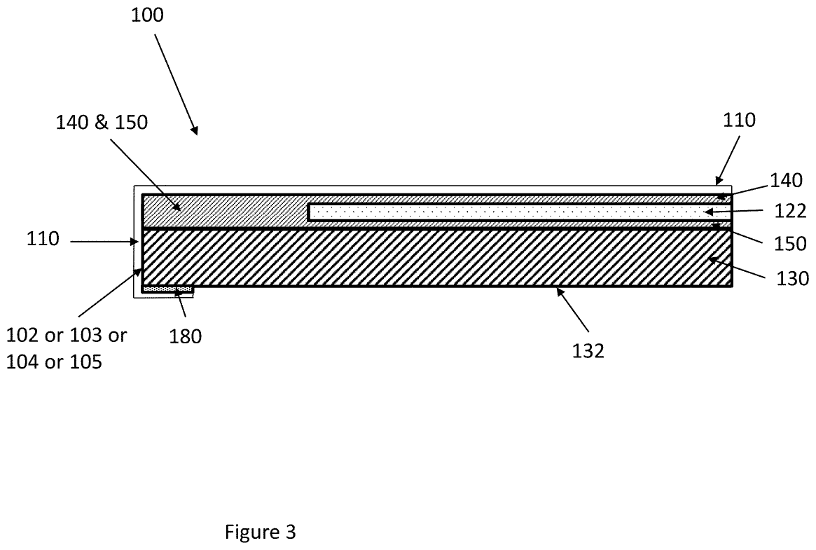

FIGS. 1a and 1b illustrate perspective views of a preferred module configuration of this invention. FIGS. 2a and 2b show a corresponding front view and rear view of the preferred module, respectively. FIG. 3 shows detailed cross section view of the preferred module configuration. Laminated photovoltaic module 100 is sized as 990 mm×1383 mm with a thickness of 4 mm, and with either rounded corners or substantially right angle corners. Of course, the module 100 may be any suitable size and shape useful in different applications.

As shown in FIG. 3, the module 100 preferably has a transparent top protective layer 110 that faces upward and is exposed to the sun. A middle layer comprises a plurality of photovoltaic cells 122 electrically interconnected to form a photovoltaic array below the top layer. The middle layer preferably rests on a semi-rigid lower substrate 130. The middle layer is preferably secured to the rigid lower layer by a lower adhesive layer 150. The middle layer is preferably secured to the upper protective layer 110 by an upper adhesive layer 140. The middle layer is thus encapsulated between the lower adhesive layer and the upper adhesive layer.

The upper protective layer 110 preferably provides weather protection as well as impact protection to the module 100. The upper protective layer 110 advantageously comprises of a transparent flexible polymer material, such as, but not limited to fluorocarbon co-polymers Ethylene tetrafluoroethylene (ETFE) or polyvinylidene difluoride (PVDF) or polytetrafluoroethylene (PTFE), which is formed into a film layer of suitable thickness (e.g., approximately 0.025-0.2 mm). Or more preferably a film thickness of 0.05-0.15 mm. The upper film is preferably transparent and hydrophobic and with low water vapor transport rate (WVRT). Thus, the photovoltaic cells 122 in the middle layer are exposed to direct sunlight without being exposed to water and without being exposed to direct impact by feet, falling objects, and debris. Tempered glass having a suitable thickness may also be used as the upper protective layer 110.

The semi-rigid lower layer substrate 130 preferably comprises a structural material, such as but not limited to glass or polymer or metal or fiber reinforced polymer or combinations of the above. For example, the fiber reinforced polymer (FRP) layer advantageously comprises a suitable thermoset or thermoplastic resin with stranded glass fiber reinforcement. Preferably the said FRP layer has a thickness of approximately 0.1 centimeter to 1 centimeter, and additionally, the said FRP has substantial flat lower and upper surfaces. The lower layer of FRP thus provides an advantageous combination of rigidity, light weight, very low permeability, electrical insulation, and flatness.

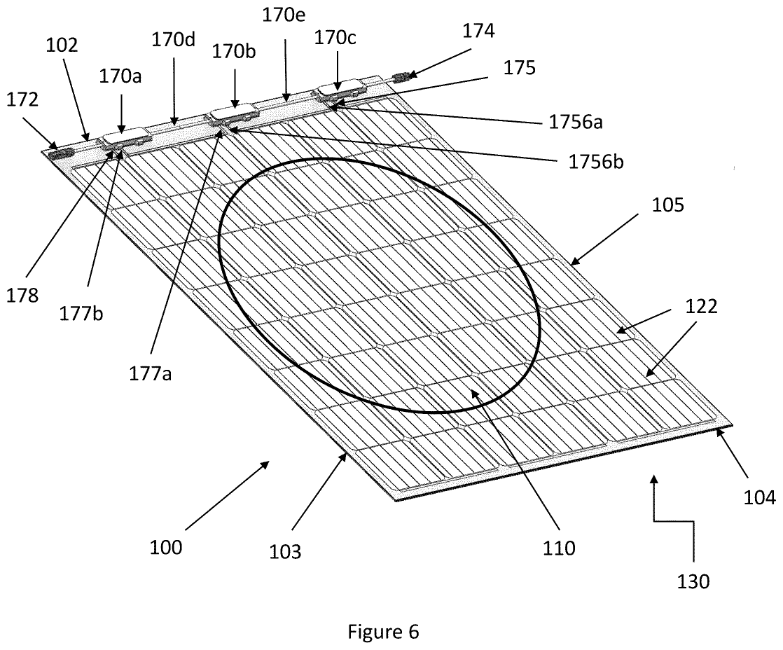

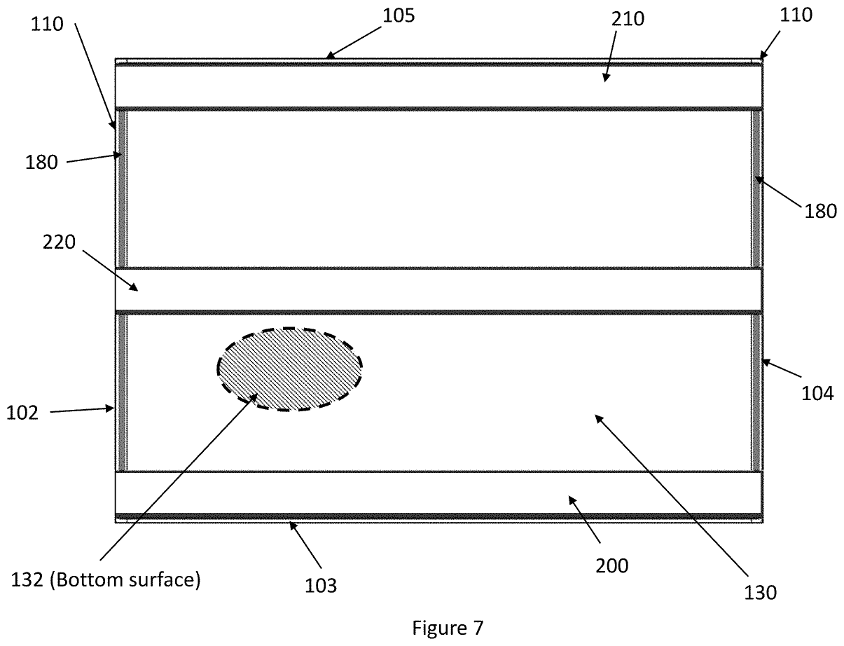

As shown in FIG. 2a, the preferred embodiment provides that the photovoltaic cells 122 are arranged in an array of 6 columns×8 rolls cells (156.75 mm×156.75 mm in dimensions). Each two column cells are electrically interconnected in a series configuration. Three 2-columns of cells are further electrically interconnected in a series configuration to provide a suitable output voltage for flat roof and sloped roof application. Photovoltaic cell array 122 is shorter than the semi-rigid substrate 130 to provide room for positioning an electrical enclosure, such as, but not limited to junction box 170 (having a first weather-resistant electrical conductor 172 and a second weather-resistant electrical conductor 174) or module level power electronic enclosures. The photovoltaic cell array 122 preferably includes four or more module output conductors that are comprised of the start and the end of each 2-column cell strings. In this preferred embodiment, four output conductors 175, 176, 177, 178 extend from the top surface of the middle layer in the area outside the photovoltaic cell array 122. Each of the module output conductors 175, 176, 177, 178 is preferably connected to one of three protective diodes within the electrical enclosure 170 in proper polarities and order after the photovoltaic module 100 is laminated, as discussed below. In an alternative embodiment, six array output conductors 175, 176a, 176b, 177a, 177b, 178 are connected to electrical junction box or MLPE enclosures which consist of up to 3 individual separated enclosures 170a, 170b, 170c with exposed flexible electrical conductors 170d, 170e electrically connecting the 3 enclosures as shown in FIG. 6. In yet another embodiment, the photovoltaic call array 122 is comprised of cut-cells, for example but not limited to ½ cut cells (156.75 mm×78.385 mm) or ⅓ cut cells (156.75 mm×52.25 mm). The cut cells are serial-parallel connected to the array output conductors 175, 176, 177, 178 for suitable module voltages.

FIG. 3 is a close-up cross section view of the FIG. 1 embodiment, showing wraparound of the upper protective layer 110 at the edge of the module 100. The upper layer 110 completely enclose all the sides 102, 103, 104, 105 of the module 100, except bottom surface of semi-rigid substrate 130 and the upper layer 110 is being fixed on the bottom surface of the substrate 130 with suitable adhesives, as shown in FIG. 2b. In this embodiment, the upper encapsulation layer 140 and lower encapsulation layer 150 are protected from direct contacts with water. Thus eliminates the need for using edge sealant materials in the frameless modules. Moisture ingress into the encapsulation layers 140 and 150 is now through the upper protection layer 110, which is selected with low water vapor transport rate. Removal of edge sealants simplifies module layup process. Furthermore remove of the edge sealant make this frameless module fabrication process closer to standard framed Si cell modules and can be easily manufactured in standard module production factories.

FIG. 2b illustrates the upper protected layer 110 is affixed on the bottom surface 132 of the semi-rigid substrate 130 after wrapping around all the sides of the module 100 peripheral outer sides: 102, 103, 104, and 105. In this preferred embodiment, fixation is done after lamination of the module 100. Fixation can be done by using, for example but not limited to, butylene adhesives, silicone, and acrylic either in tape format or liquid. A chosen adhesive 180 is placed on the surface 132 of the substrate 130 and forms a seamless profile along the surface 132 outer edges. The adhesive profile is placed from the module 100 peripheral outer edges of the surface 130 with a distance preferably 0-15 mm, or more favorably 5-8 mm. The adhesive profile is preferably with a width of 10-15 mm and a height of 0.3-1 mm. After adhesive's placement, the upper protective layer 110 can be pressed on the top of adhesive 180.

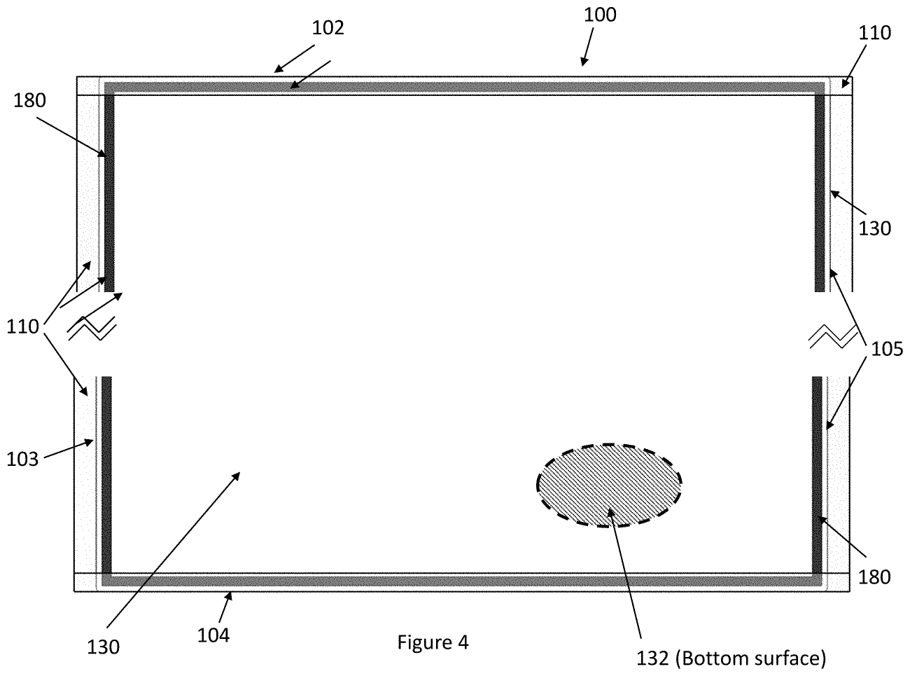

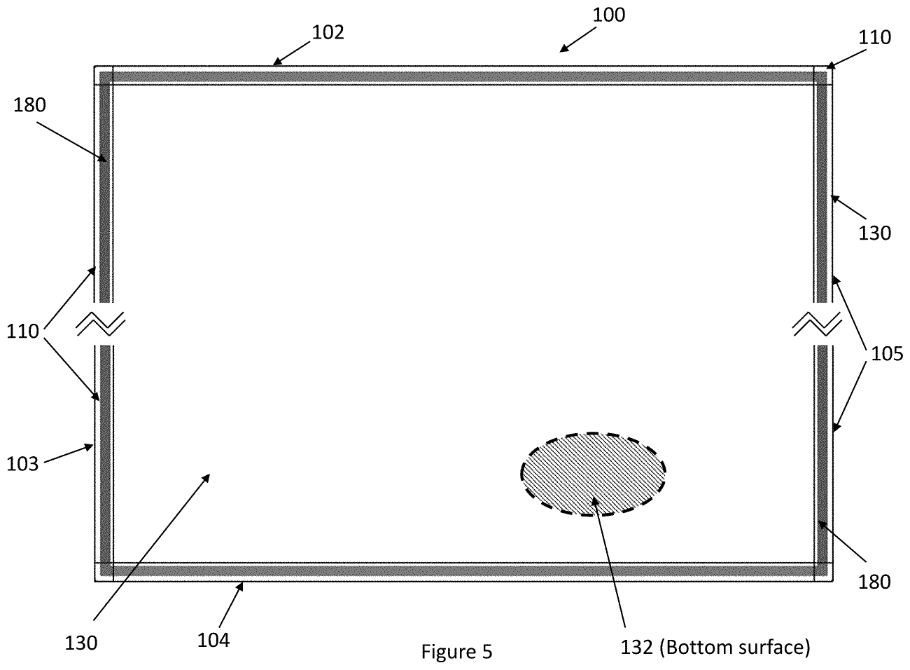

A preferred embodiment of affixing the upper protective layer 110 on the semi-rigid substrate 130 is shown in FIGS. 4 and 5. As shown in FIG. 4, the upper layer 110 is folded along the substrate 130 short edges 102 and 104 first, and adhere to the substrate surface 132 by press on the adhesive profile along the short edges. Then the upper layer 110 is folded along the substrate 130 long edges and adhere to the substrate surface 132 by press on the adhesive profile along the long edges 103 and 105 as shown in FIG. 5. Alternatively, one can do this in the opposite sequence.

A preferred method of installation of the module 100 on a roof comprises applying a double stick suitable construction tape, such as but not limit to pressure sensitive butylene Peel-And-Stick (PAS) tape (commonly used in construction industry) to the bottom surface 132 of the semi-rigid substrate 130, as shown in FIG. 6. PAS tape position is designed to further secure the portion of upper protective layer 110 fixed on the bottom surface 132: A first PAS tape 200 is placed parallel to the first long edge 103 of the substrate 130 in a distance less than 20 mm from the said long edge and run from a first short edge 102 of the substrate 130 to the opposite short edge 104 continuously. A second PAS tape 210 is placed parallel to the second long edge 105 of the substrate 130 in a distance less than 20 mm from the said second long edge and run from the first short edge 102 of the substrate 130 to the opposite short edge 104 continuously. Preferably one more PAS tape 220 is placed between the said first and second PAS tape to provide increased security for the module 100 installation on roofs. Of course, more PAS tapes can be added for additional The PAS double-stick tapes are installed on to the module substrate 130 in the module factory after the upper layer 110 fixation on the substrate surface 132. Thus the PAS tapes cover the fold corner portions of the upper protective layer 110 on the substrate surface 132 and protect the said folded upper layer 110. One release layer is advantageously put on the surface of the installed PAS tape that is facing away from the module 100 for easy of module handling and transportation. The said release layer is removed when the module 100 is being installed so that the module can be adhered to the surface of an existing roof.

1. A photovoltaic module, comprising:
a semi-rigid substrate layer;
a photovoltaic layer positioned above the semi-rigid substrate layer, the photovoltaic layer comprising a plurality of electrically interconnected photovoltaic cells disposed in an array;
an encapsulating material encapsulating the photovoltaic layer;
an upper transparent protective layer disposed (i) above the photovoltaic layer, (ii) above the encapsulating material, (iii) out portion of the upper transparent protective is bend next to be vertically adjacent to the encapsulating material and photovoltaic layer and semi-rigid substrate, (iv) a portion the out portion of the upper transparent protective layer is further bend beneath the semi-rigid substrate, (v) the out portion of the upper transparent protective layer beneath the semi-rigid substrate is affixed to the semi-rigid substrate to form a water barrier for the photovoltaic layer and the encapsulating material.

2. The photovoltaic module according to claim 1, wherein the encapsulating material is enclosed by the upper transparent protective layer and the semi-rigid substrate layer and no direct exposure to ambient.

3. The photovoltaic module according to claim 1, wherein the upper transparent protective layer is bond to the top surface of the semi-rigid substrate with the encapsulation layers and a portion of out portion of the upper transparent protective layer is further bond to the bottom surface of semi-rigid substrate with a different adhesive material.

4. The photovoltaic module according to claim 1, wherein a portion of the upper transparent protective layer is substantially perpendicular to the photovoltaic layer.

5. The photovoltaic module according to claim 1, wherein a portion of the upper transparent protective layer is substantially perpendicular to the semi-rigid substrate.

6. The photovoltaic module according to claim 1, wherein the adhesives between the upper transparent protective layer and the bottom surface of the semi-rigid substrate is comprise of seamless profile along the out edges of the said substrate.

7. A photovoltaic module, comprising:
a semi-rigid substrate layer;
a photovoltaic layer positioned above the semi-rigid substrate layer, the photovoltaic layer comprising (i) a plurality of electrically interconnected photovoltaic cells disposed in an array and (ii) electrical conductors connecting the array to electrical enclosure disposed above the array;
a first heat activated transparent insulating adhesive layer disposed between the semi-rigid substrate and the photovoltaic layer to adhere the photovoltaic layer to the substrate layer;
an upper transparent protective layer disposed (i) above the photovoltaic layer, (ii) above a second heat activated transparent insulating adhesive layer, which is disposed between the photovoltaic layer and an upper transparent protective layer to adhere the photovoltaic layer to the upper transparent protective layer;
the first and second layers of heat-activated transparent insulating adhesives encapsulate the photovoltaic layer;
an outer portion of the upper transparent protective layer is bend next to be vertically adjacent to the encapsulating material and photovoltaic layer and semi-rigid substrate;
a portion the out portion of the upper transparent protective layer is further bend beneath the semi-rigid substrate; and
the out portion of the upper transparent protective layer beneath the semi-rigid substrate is affixed to the semi-rigid substrate to form a water barrier for the photovoltaic layer and the encapsulating material.

8. The photovoltaic module according to claim 7, wherein said electrical enclosure box is disposed at a position adjacent to the photovoltaic layer and on the upper transparent protective layer adjacent to a first edge of the rectangular module.

9. The photovoltaic module according to claim 7, wherein said first edge comprises an upper protective layer wrapped module edge.

10. A frameless photovoltaic module comprising:
a substantially rectangular panel having a semi-rigid substrate and a flexible top transparent protective layer with a plurality of photovoltaic cells disposed between them in an array;
an electrical device disposed on the said top transparent layer's top surface and substantially adjacent a first edge of the rectangular panel; and
a said top transparent protective layer continuously wrapped around said photovoltaic cell array and said semi-rigid substrate in a substantial perpendicular manner to the photovoltaic array and the substrate.

11. The photovoltaic module according to claim 10, wherein heat-activated encapsulation material layers between said top layer and substrate has no direct contact with ambient.

12. The photovoltaic module according to claim 10, wherein said heat-activated encapsulation material layer between said top layer and substrate is covered vertically along the peripheral outer edge of the module.

13. The photovoltaic module according to claim 10, wherein said top transparent protective layer is further folded along the peripheral outer edge of the said semi-rigid substrate and affixed to the bottom surface of the substrate.

14. A method of making a frameless top transparent protective layer sealed photovoltaic module, comprising:
disposing a photovoltaic layer on a semi-rigid substrate and under a transparent top protective layer, the transparent top protective layer being wider and longer than the semi-rigid substrate, the semi-rigid substrate being wide and longer than the photovoltaic layer;
forming a sealed layer sideways adjacent to (i) the photovoltaic layer, (ii) at least an out edge of the semi-rigid substrate, and (iii) the surface of the semi-rigid substrate facing away from the photovoltaic layer; and
forming a protective layer over the photovoltaic layer.
